(19) United States
(12) Patent Application Publication
(10) Pub. No.: US 2005/0079684 A1
(43) Pub. Date: Apr. 14, 2005

(54) Method of manufacturing an accelerometer

(76) Inventors: Wai Mun Chong, Singapore (SG); Kim Pong Daniel Chir, Singapore (SG); Kitt Wai Kok, Singapore (SG); Sooriakumar Kathirgamasundaram, Singapore (SG); Bryan Keith Patmon, Singapore (SG)

Correspondence Address: David G Latwesen;Wells St John, 601 West First Avenue, Suite 1300, Spokane, WA, 99201-3828, US

(21) Appl. No.: 10/503,288

(22) PCT Filed: Jan. 29, 2003
(86) PCT No.: PCT/SG03/00019

(30) Foreign Application Priority Data
Jan. 29, 2002 (SG) 200200518-9

(51) Int. Cl. H01L 21/30

(52) U.S. Cl. 438/455

(57) ABSTRACT

Devices fabricated on a wafer are encapsulated by forming a pattern of bond rings on a cap wafer and aligning and bonding the two wafers together, under thermo-compression, so that an operational part (22) of each device (20) is surrounded by a respective bond ring (21). The bond ring provides a hermetic seal by occupying any trenches (25) or other discontinuities, such as conductive tracks (23), in the upper surface of the device crossed by the ring. An accelerometer is manufactured by etching at least one cavity (5) into the top side of a substrate (1), bonding an intermediate layer of material (6) onto the top side of the substrate, depositing metallization (7) onto the intermediate layer and etching the metallization and intermediate layer to form a sensor structure suspended over each cavity. Conductive tracks (31, 32) of a lower metallization layer deposited on the substrate (30) cross under tracks (37, 38) deposited on the upper side of the intermediate layer (35, 36) without making electrical connection. Bridges are fabricated by forming cavities (33, 34) on the underside of the intermediate layer to accommodate the lower track.

### FIELD OF INVENTION

The invention relates to microelectromechanical and microelectronic devices and methods of their manufacture, and in particular to inertial devices, for example accelerometers or gyroscopes, which require suspended mass. The invention also relates to methods of encapsulating and hermetically sealing wafer-fabricated devices having deep isolation trenches, and to methods of making electrical connections to microelectromechanical and microelectronic devices.

### BACKGROUND

Microelectromechanical inertial devices are currently being manufactured for a number of applications including vehicle airbag and inertial navigation and guidance systems. For applications such as vehicle airbags the inertial devices, for example accelerometers, need to be both accurate and inexpensive.

Microelectromechanical accelerometers are formed on a substrate using fabrication process steps similar or identical to those used in integrated circuit fabrication. Microelectromechanical devices combine electrical and mechanical functionality into one device. The fabrication of microelectromechanical devices is generally based on the making and processing of alternate layer of polycrystalline silicon (polysilicon) and a sacrificial material such as silicon dioxide (SiO₂) or a silicate glass. The polysilicon layers are built up and patterned layer by layer to form the structure of the device. Once the structure is completed the sacrificial material is removed by etching to release the polysilicon members of the microelectromechanical device for operation. The removal of sacrificial material in some microelectromechanical accelerometers includes using an isotropic release etch to release beams of the accelerometer from the bottom surface of the accelerometer. This release etch has the disadvantage of etching away part of the beams and reducing the proof mass and effectiveness of the accelerometer.

Microelectromechanical and microelectronic devices are preferably encapsulated and hermetically sealed at the wafer fabrication stage, i.e. as part of the basic device fabrication. However, obtaining a seal with a high degree of hermeticity is difficult, particularly when there are deep trenches that isolate electrical runners which are not in the plane of the upper surface of the device.

Furthermore, in the prior art, interconnections from the device to external connection terminals have been provided by electrical runners which sometimes follow circuitous routes requiring a large overhead in wafer area. Where trenches are required to isolate adjacent runners, the additional wafer area required is even larger. In some cases this problem has been addressed in the prior art by using crossing connections, for example by double layers of metallization. This requires passivation and in some cases planarization of dielectric layers, which introduce further complexity and problems.

### SUMMARY OF INVENTION

It is an object of one embodiment of the invention to provide an accelerometer or other inertial device by a method which reduces at least some of the prior art problems associated with etching and releasing of beam structures.

It is an object of a second embodiment of the invention to provide a method of encapsulating and hermetically sealing a device manufactured by wafer fabrication, and particularly such devices incorporating deep isolation trenches.

It is an object of a third embodiment of the invention to provide a method of manufacturing a wafer-fabricated device having electrically-isolated conductive tracks crossing one another.

It is an object of a fourth embodiment of the invention to provide a method of manufacturing and hermetically encapsulating microelectromechanical and microelectronic devices incorporating deep isolation trenches and crossed electrical connections by multiple wafer metallization layers.

In broad terms in one aspect the invention comprises a method for fabricating an accelerometer including the steps of; etching at least one cavity into the top side of a substrate, bonding a layer of material onto the top side of the substrate, depositing metalisation onto the layer of material to be used for electrical connections and etching the layer of material to form at least two independent sets of beams over each cavity.

Preferably the substrate is an insulating material. Ideally the substrate is formed from glass or another equivalent material.

Preferably each set of beams is anchored to the substrate.

Preferably one set of beams includes means to allow the beams to move with side to side motion from one end of the beams. Ideally the means to allow the beams to move is a spring or tether means.

Preferably the method of fabricating the accelerometer further includes the step of masking the substrate before the step of etching the substrate.

Preferably the method of fabricating the accelerometer further includes the step of patterning the mask using lithography processes.

Preferably the layer of suitable material is a silicon material.

Preferably the layer of suitable material is thinned as required.

Preferably the method of fabricating the accelerometer further includes the step of masking the layer of suitable material before the step of etching the sets of beams.

Preferably the method of fabricating the accelerometer further includes the step of patterning the masking layer to the pattern of the beams prior to the step of etching the sets of beams.

Preferably the method of fabricating the accelerometer further includes the step of performing an etchback to remove the unwanted masking layer after the sets of beams have been etched.

In broad terms in a further aspect the invention comprises an accelerometer including; a bottom substrate layer, at least one cavity in the bottom substrate layer, an upper layer, at least two sets of beams formed in the upper layer and suspended over the cavity, at least one point suitable for electrical connection to each set of beams, wherein the cavity is formed before the suspended beams are formed.

In another aspect, the invention may be broadly said to be a method of bonding a cap wafer to a device wafer, the device wafer having a substrate and a pattern of individual devices fabricated on one face of the substrate, the method including the following steps performed in the order recited:
(a) forming glass bond rings on one face of the cap wafer, the bond rings being dimensioned and arranged on the cap wafer for respectively surrounding the individual devices on the device wafer when the cap wafer is aligned with the device wafer;
(b) aligning and placing the cap wafer on the device wafer with said one face of the cap wafer adjacent the one face of the substrate on which is formed the pattern of individual devices, the two wafers being aligned with the bond rings respectively surrounding the individual devices;
(c) exposing the aligned wafers to a vacuum, and increasing the temperature of the wafers to a predetermined bonding temperature;
(d) applying a force to urge the aligned wafers together and to compress the bond rings;
(e) reducing the temperature of the wafers to room temperature and removing the force when the temperature of the wafers is less than a first predetermined temperature; and
(f) venting the vacuum to atmosphere when the temperature of the wafers is less than a second predetermined temperature.

Preferably, the pattern of individual devices is fabricated by forming one or more layers on the one face of the substrate, and the outermost of the one or more layers has open trenches.

Preferably, the bond rings, in conjunction with respective portions of the cap wafer, provide respective hermetic seals around and over the individual devices, after performance of said steps (a) to (f).

Preferably, a full width portion of each said trench of a device is crossed by, and substantially occupied by, a portion of the respective bond ring.

Preferably, step (a) includes the following steps (g) to (n) performed in the order recited:
(g) preparing a glass paste by mixing a glass powder with a vehicle liquid;
(h) coating the one face of the cap wafer with a layer of the glass paste;
(i) pre-firing the glass paste at a pre-firing temperature;
(j) applying a layer of resist over the layer of glass paste;
(k) soft baking the resist layer;
(l) photo-lithographically patterning and developing the applied resist layer;
(m) hard baking the developed resist layer; and
(n) etching the layer of glass paste to form glass bond rings on the one face of the cap wafer, the bond rings being dimensioned and arranged on the cap wafer for respectively surrounding individual devices on the device wafer when the cap wafer is aligned with the device wafer.

In yet another aspect, the invention may be broadly said to be a sealed device, the device being fabricated from one or more layers formed on one face of a substrate, the device having a cap which is bonded to the outermost surface of said layers by a bond ring, the bond ring surrounding and hermetically sealing at least an operational portion of the device.

In yet another aspect, the invention may be broadly said to be a method of manufacturing a wafer fabricated device including the steps of:
(o) depositing a first metallization onto one side of a substrate,
(p) selectively etching the deposited first metallization to provide a pattern including at least one conductive track,
(q) selectively etching at least one cavity in a first face of a wafer,
(r) bonding the etched first face of the wafer to the top side of the substrate, so that the cavity overlies the at least one conductive track,
(s) depositing a second metallization onto the outer face of the bonded wafer,
(t) selectively etching the second metallization to provide a pattern including at least one conductive path, the conductive path overlying but not making electrically conductive connection with, the conductive track, and
(u) selectively etching the wafer to provide a device structure.

The invention may further be said to consist in any alternative combination of parts or features mentioned herein or shown in the accompanying drawings. Known equivalents of these parts or features which are not expressly set out are nevertheless deemed to be included.

### BRIEF DESCRIPTION OF DRAWINGS

Preferred forms, systems and methods of the invention will be further described with reference to the accompanying figures by way of example only and without intending to be limiting, wherein;

FIG. 1A shows a glass substrate with a masking layer,

FIG. 1B shows a substrate with an insulating layer and a masking layer,

FIG. 2 shows the substrate with the masking layer patterned,

FIG. 3 shows the substrate with cavities etched into the substrate,

FIG. 4 shows the top layer bonded to the substrate,

FIG. 5 shows the top layer thinned to the required thickness,

FIG. 6 shows the deposition of metalisation on the top layer,

FIG. 7 shows the metalisation patterned to form electrical connections,

FIG. 8 shows a masking layer over the top layer and metalisation patterned to the accelerometer sensor pattern,

FIG. 9 shows the results of a trench etch producing the accelerometer sensor pattern,

FIG. 10 shows the results of an etchback which has removed the masking layer,

FIG. 11 is a top view of an accelerometer formed using the method of the invention,

FIG. 12 is a flow chart of a method for capping devices such as the accelerometer,

FIG. 13 is a flow chart of further detail of step 2 of FIG. 12,

FIG. 14 is layout view of a device wafer showing an accelerometer device bounded by a bond ring,

FIG. 15 is a diagrammatic cross-section of a portion of the capped wafer at line X-X′ of FIG. 14, and

FIG. 16 is a perspective view of a small fragment of a bonded wafer pair, showing electrically isolated and electrically connecting cross-over connections between conductive tracks of upper and lower metallization layers.

### DETAILED DESCRIPTION OF PREFERRED FORMS

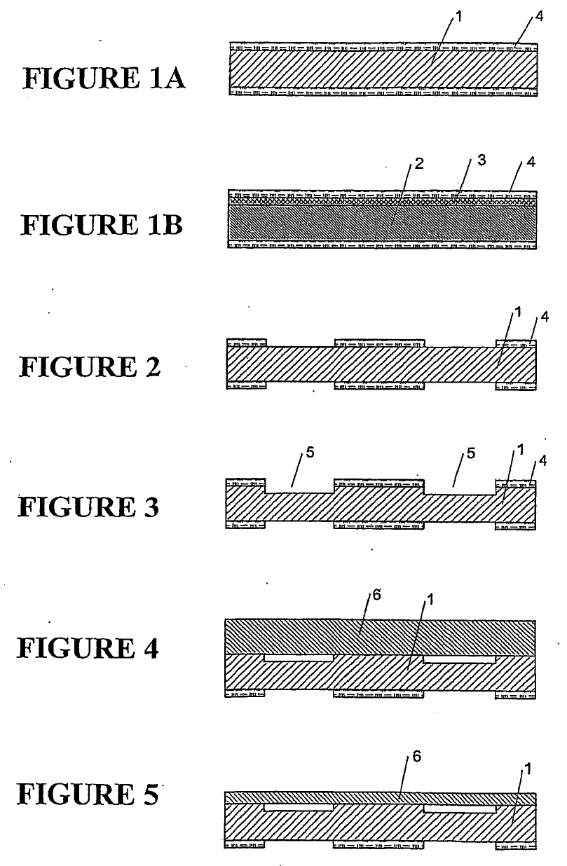

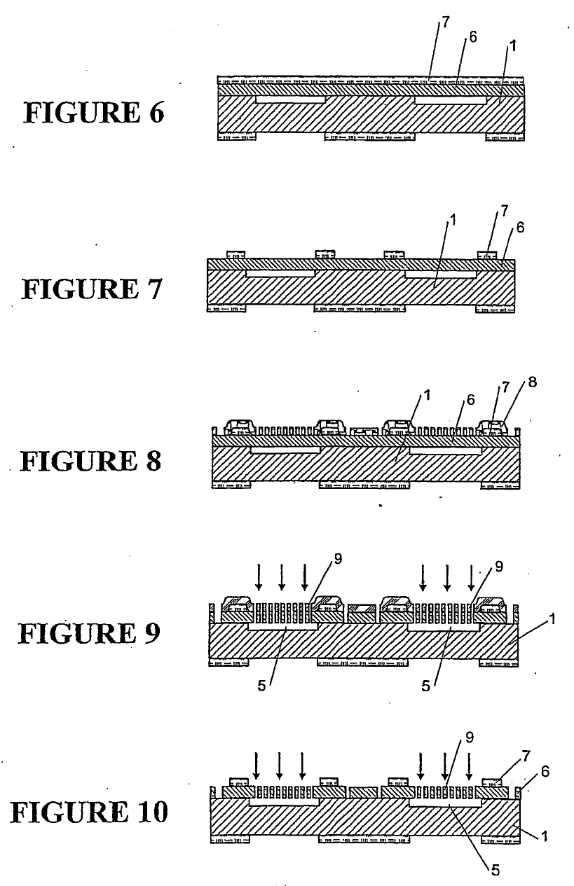

FIG. 1A shows a substrate 1 of electrically insulating material. The substrate is covered by masking layer 4 on its top surface. Substrate 1 may be formed from any suitable electrically insulating material such as glass, Pyrex or other materials with similar properties.

FIG. 1B shows an alternative wafer arrangement where the substrate 2 is from of electrically conducting or semiconducting material such as silicon. In this arrangement substrate 2 has an electrically insulating layer 3 deposited on its top surface. Suitable materials for the insulating layer include oxide, nitride, PSG, glass frit, etc.

In both the arrangements of FIGS. 1A and 1B the top surface of the substrate 1 or the insulating layer 3 is deposition with a masking layer 4. The masking layer is patterned with marks for cavities to be formed in the substrate 1 (of the wafer of FIG. 1A) or insulating layer 3 and substrate 2 (of the wafer of FIG. 1B). The masking layer may also be patterned with marks for alignment purposes useful for later stage of the process. The masking layer may be formed from chrome or any other suitable material, for example polysilicon. FIG. 2 shows the masking layer once it has been patterned. Patterning of the masking layer may be using lithography processes as are well known to those skilled in the art and commonly used in the wafer fabrication industry.

FIG. 3 shows cavities 5 etched into the substrate 1. Etching may be performed using any suitable process such as anisotropic etching. After the cavities have been etched the remaining masking layer is removed.

Following this a top layer of semiconducting material 6 such as silicon is bonded to the substrate 1 as shown in FIG. 4. Any suitable bonding technique may be used to bond the two layers together. For example a suitable technique may be anodic, eutectic or thermocompression bonding. Alternatively any other suitable technique may be used. If the top layer 6 is thicker than the thickness required for the sensor it is thinned to the required thickness. Techniques for thinning the top layer include wet chemical etching, backgrinding, lapping, chemical-mechanical polishing or a combination of these and other techniques.

FIG. 5 shows the top layer 6 and substrate 1 bonded together with the top layer at the required thickness. The thickness of the top layer determines the thickness of the beams of the sensor. The capacitance of the sensor formed by the process is also related to the thickness of the beams. The sensitivity of the sensor to acceleration forces is also related to the thickness of the beams. The thicker the beams the bigger the capacitive charge for a given displacement of the beams. Another effect of thicker beams is a larger seismic or proof mass of the sensor. This also increases the sensitivity of the sensor to low g-forces.

Following the step of bonding the substrate 1 and the top layer 6 and the step of thinning the top layer (if necessary), metallization 7 is deposited onto the top of top layer 6. Metallization is used to form electrical connections to further electronics to be connected to the sensor. FIG. 7 shows the patterning of metallization 7 to form the electrical connections.

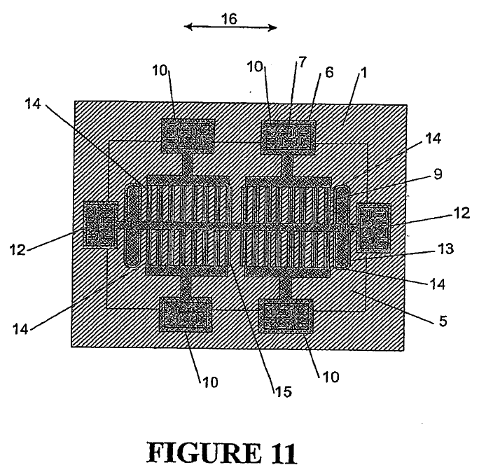

The next step in the process is to deposit a masking layer 8 over the metallization 7 and the top layer 6. Again the masking layer 8 is patterned using a suitable process such as a lithography process. As can be seen in FIG. 8, the masking layer has been patterned to form the sensor structure of the accelerometer. In this case the sensor structure of the accelerometer includes two comb like structure on each side of the cavity and a central beam with a comb like structure on each side. Each of the comb like structures extending from the central beam intermeshes with one or the other comb like structures (shown in more detail in FIG. 11). However other suitable structures may be patterned onto the mask.

Following the patterning of the mask the mask is then etched as shown in FIG. 9 to produce the structure of the sensor suspended over cavities 5 in substrate 1. This etch step may be performed by anisotropic etch. The step of forming cavities 5 in substrate 1 before bonding top layer 6 to the substrate removes the need to etch underneath the beams of the sensor to release them from the substrate by isotropic etching. This avoids the problems associated with isotropic etching including that isotropic etching consumes much of the thickness of the beams thereby reducing the sensitivity and capacitance of the sensor.

The final step in the process is performing an etch back to remove the unwanted masking layer 9 from the top of the sensor as shown in FIG. 10. A further optional step is to provide a passivation layer over the metallization. The sensor is now functional and can be packaged on to a wafer level to enable dicing the wafers into individual dies.

FIG. 11 is a top view of a sensor formed using the method of the invention. As can be seen in FIG. 11 the sensor structure is suspended over cavity 5. The sensor structure comprises four sets of fixed capacitive plates anchored to substrate 1 at anchor blocks 10. Each set of capacitive plates includes a set of beams attached at one end to a wider beam in a comb arrangement. The wider beam is then attached to the anchor block. A second set of capacitive plates is shown at 15. This set of capacitive plates has a central wider beam with smaller beams extending at right angles from both sides of the wider beam. The wider beam of this set of capacitive plates is tethered to anchors 12 by spring means 13. The spring means 13 allows capacitive plates 15 to move in the directions indicated by arrow 16. Any suitable means that allows movement of the capacitive plates in one direction may be used.

Each anchor block 10 or 12 includes an area 7 of metallization used for electrical contacts. The electrical contacts may also be provided at other area of the wafer connected to the anchor blocks 10 or 12. Although the anchor blocks all rest on the same substrate, the insulating properties of the bottom wafer keep the anchor blocks electrically insulated from one another. Cavity 5 under the structure, in the bottom wafer, allows the structure to be suspended and freely react to acceleration forces parallel to the wafer surface. This allows a capacitance change caused by a force displacing the moving plates relative to the fixed plates to be sensed.

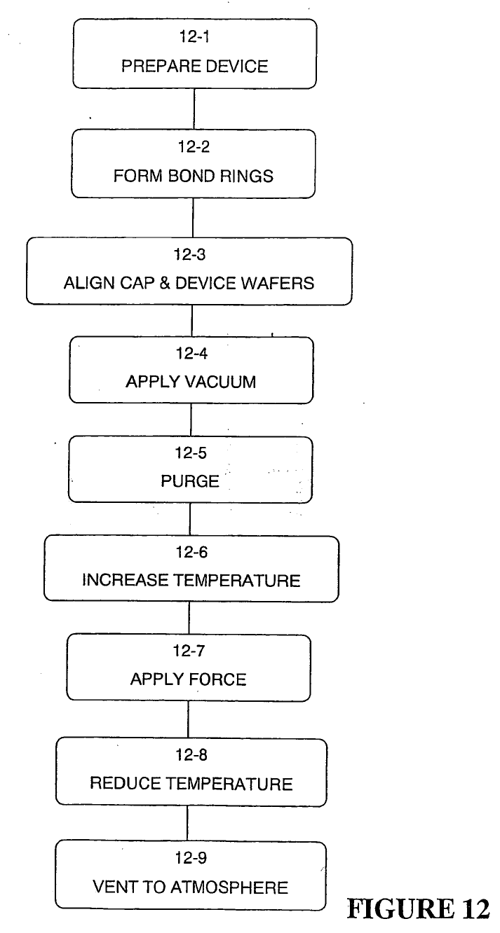

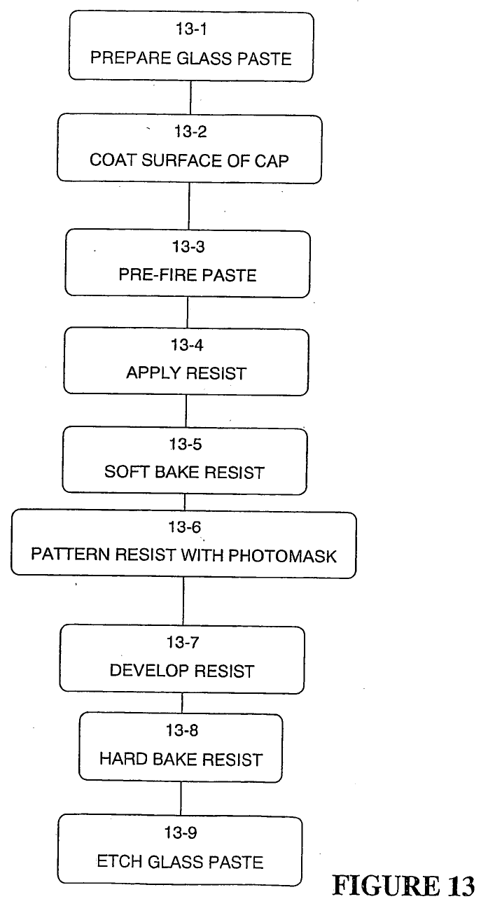

FIGS. 12 and 13 show steps of a method by which the accelerometer as described above, or other devices formed by wafer fabrication techniques, may be capped and hermetically sealed by a wafer cap which is bonded and sealed to the device by a glass bond ring, as will be described in more detail below.

A device wafer bearing an array or pattern of accelerometers or other devices is prepared in the manner described above or by other wafer fabrication processes as are well known in the art of wafer fabrication. This process is represented in FIG. 12 as step 12-1.

A pattern of bond rings is formed on one face of a cap wafer, as indicated by step 12-2 of FIG. 12. In a preferred embodiment the cap wafer is wafer of silicon material. The pattern of bond rings is formed so that when the cap wafer and the device wafer are aligned, the bond rings surround at least an operational portion of respective devices on the device wafer. A preferred photo-lithographic method by which the bond rings are formed on the cap wafer (step 12-2 of FIG. 12) is described in more detail by the process shown in FIG. 13.

Referring to FIG. 13, and step 13-1 in particular, a glass paste is prepared by mixing a frit vehicle liquid with a powder of frit or ferro glass. For example, 20 ml of a vehicle liquid is poured onto 150 gm of frit or ferro glass powder and mixed well for at least 5 minutes. The nominal particle size of the glass powder is preferably between about 15 μm and about 40 μm. One suitable powder is a ferro glass powder of 15 μm nominal particle size. More preferably, the glass paste is made with a frit glass powder of 40 μm nominal particle size. In general, the particle size of the powder is chosen to suit the width and height of trenches or channels in the upper surface of the device being encapsulated.

One face of the cap wafer is coated (step 13-2 of FIG. 13) with a layer of the glass paste which may be globally applied over the full face of the wafer by a suitable screen printing technique, as is well known to one skilled in the art of wafer fabrication. It is preferred that the cap wafer be coated with a freshly prepared paste. In particular, the paste is preferably used on the day of its preparation.

The applied glass paste layer is pre-fired (step 13-3 of FIG. 13) at a temperature of between about 350° C. and 425° C., and preferably at about 400° C.

The thickness of the glass layer may be then measured to confirm that a suitable thickness has been achieved. A preferred thickness is between about 80 μm and 120 μm in the case where the trenches (as will be explained further, below) are about 30 μm to 40 μm deep. In general, the preferred thickness of the glass layer is at least 20% greater than the depth of the trenches. Particularly, the thickness of the glass layer is about double the depth of the trenches.

The bond rings are formed from the glass layer by a photo-lithographic process that follows basic steps that are well known in the art of wafer fabrication.

The fired glass layer is coated with a resist layer (step 134 of FIG. 13).

The resist layer is soft baked (step 13-5 of FIG. 13), preferably at a temperature of 90° C. A preferred thickness of the resist layer is about 6 μm.

The resist layer is photo-graphically exposed (step 13-6 of FIG. 13) to a bond ring pattern. The pattern of bond rings is such that when the cap wafer is aligned with the device wafer, the bond rings respectively outline at least an operational portion of each accelerometer or other device on the device wafer. The width of the wall of the bond rings is preferably about 325 μm to 350 μm.

The resist is developed (step 13-7 of FIG. 13) and then hard baked (step 13-8 of FIG. 13), the hard bake temperature being preferably 100° C.

The bond rings are formed by etching the fired glass paste (step 13-9 of FIG. 13) by a suitable etch method as is well known in the art. For example, wet etching with nitric acid at a concentration of 15:1 to form the bond rings on the cap wafer.

The width of the photo-lithographically printed bond rings may be measured to confirm that the desired width has been achieved.

Although not shown in the figures, the cap wafer may be trimmed by sawing to provide an alignment edge and the back face (i.e. the face opposed to the face with the formed bond rings) may be pre-sawn for eventual dicing.

The finished cap wafer may then be glazed (not shown in the figures) to drive out any residual moisture, e.g. from the nitric etch acid.

As noted above, steps 13-1 to 13-9 of FIG. 13 provide details of a preferred process by which step 12-2 of FIG. 12 may be performed. A description of the further steps 12-3 to 12-9 of the process shown in FIG. 12 follows.

The cap wafer, with the pattern of formed bond rings, is aligned (step 12-3 of FIG. 12) with the device wafer, on which has been prepared an array of individual devices. The cap and device wafers are juxtaposed so that the face of the cap wafer having the bond rings is adjacent the face of the device wafer having the array of devices.

The aligned wafers, supported in a chuck, are placed in a bonder chamber. The chamber is pumped down to expose the wafers to a vacuum (step 12-4 of FIG. 12). The air pressure in the chamber is decreased, and stabilised at a pressure of about 5 mb for about 2.5 minutes to purge gases from the chamber and from the wafers (step 12-5 of FIG. 12).

The vacuum is maintained, and the temperature increased (step 12-6 of FIG. 12) from room temperature to an initial target of 440° C. over about 2 minutes. The temperature is then further raised to a bonding temperature. The value of the bonding temperature in degrees Celsius is preferably about 10% higher than the Celsius value of the pre-firing temperature of step 13-3 in FIG. 13. A preferred bonding temperature is about 450° C.

A piston is lowered onto the upper wafer and a biasing force applied to urge the two wafers together (step 12-7 of FIG. 12). When exposed to the bonding temperature, the formed bond rings soften to a semi-solid state so that, particularly under the applied biasing pressure, the glass material of the rings can flow into any trench or open channel crossed by the ring material.

Such trenches may be provided in a upper layer or layers of the devices being capped. When these layers are conductive or semi-conductive, the trenches enhance the electrical insulation between the remaining portions of these layers adjacent either side of the trench. It is known to cut such trenches so that they extend down to the underlying insulative substrate or layer, for example the substrate 1 or the insulating layer 3 of the accelerometer as described above. Typically, these trenches have a width of between about 50 μm and 60 μm, and are about 30 μm deep.

The applied biasing force is increased gradually so that the bond ring material can accommodate to the topography of the device, and the integrity of the rings can be maintained. This helps to reduce the likelihood of breaks in the bond rings.

In one preferred method, an initial biasing force of 10 Newton is applied and held for 15 seconds before being increased to 100 Newton which is held for 15 seconds, followed by successive increases to 1000, 1300, 1600, 1900, 2100, 2400 and 2700 Newton, holding the applied biasing-force at each level for 10 seconds, before proceeding to the next higher level, and finally maintaining the force at 3500 Newton for about 27 minutes.

The heating is then turned off (step 12-8 in FIG. 12), and the wafers allowed to cool toward ambient i.e. room temperature.

When the wafer temperature reaches a first predetermined temperature, for example 350° C., the piston is lifted to remove the applied biasing force.

When the wafer temperature has decreased to no more than a second predetermined temperature, for example 250° C., the bonder chamber is vented to release the vacuum (step 12-9 in FIG. 12). The vacuum is preferably not released before the wafers have cooled to a low temperature, to reduce the likelihood of wafer damage due to thermal shock caused by the introduction of air at room temperature.

The two wafers are bonded together by the bond rings which conform to the upper surface of the devices formed on the device wafer to provide effective hermetic seals.

After bonding of the two wafers, the combined wafers are diced to provide individual hermetically sealed devices.

The described capping method provides for effective hermetic sealing of the cap wafer over each device by respective bond rings. This sealing is achieved in part by the flowing or conforming of the glass bond ring material where it crosses any trenches or other irregularities in the upper surfaces of the devices.

It is to be understood the performance of method steps in the order recited does not exclude other steps intermediate the recited steps. For example, it is known to include one or more rinsing steps as part of the etching process. It is also known to trim the wafers to provide an alignment reference edge. Such steps have not been specifically recited but are understood to be not excluded from the methods described and claimed.

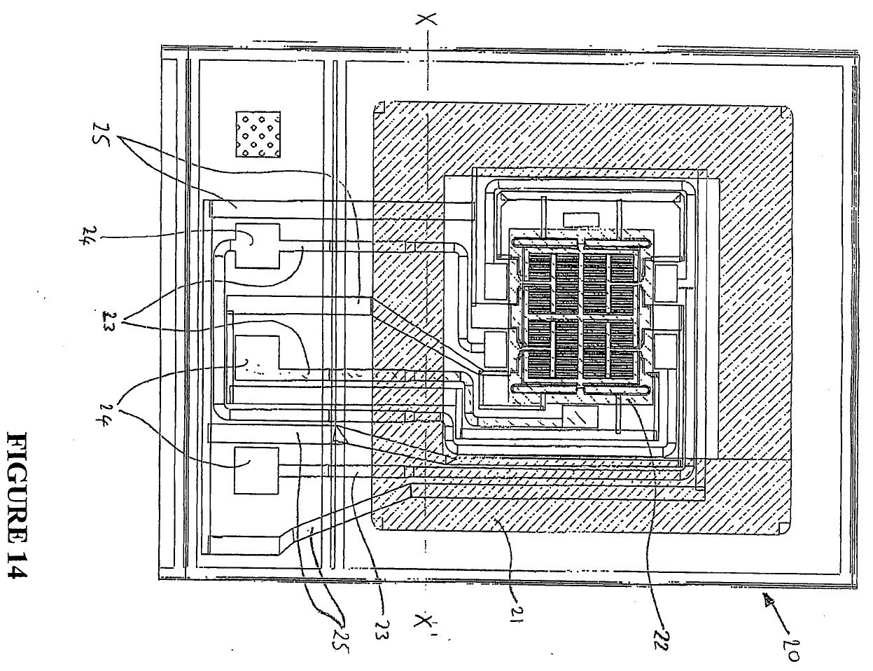

FIG. 14 shows a layout of an accelerometer as a single fabricated device 20. As will be understood by those skilled in the art of wafer fabrication, many such devices are fabricated in an array on a single wafer. FIG. 14 also shows the location of a bond ring 21. The bond ring surrounds the operational part 22 of the device. Conductive tracks 23, such as provided by an applied metallization layer, pass under the bond ring to connect the operational part of the device inside the bond ring to connecting pads 24 outside the bond ring. Trenches 25 are provided adjacent and between connecting tracks 23, and adjacent and between associated pads 24, to enhance the electrical isolation between the adjacent tracks and pads. Connecting wires (not shown) are bonded to the pads for connecting the device to other circuit elements or to leads on a lead frame.

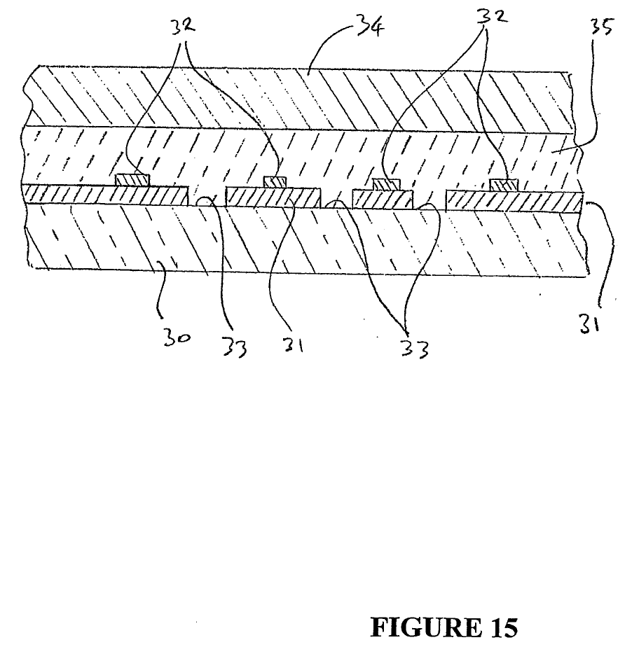

FIG. 15 shows a diagrammatic cross-sectional view of a fragment of the bonded wafers, along the line X-X′ of FIG. 14. FIG. 15 is not to scale being purely for the purposes of explanation. FIG. 15 shows a fragment of a capped device, having a device substrate 30 and a device layer 31. The device layer is typically made of silicon, but may be made from any other suitable material. Conductive tracks 32 are provided on the device layer 31 by selective etching of a metallization layer. The device layer 31 is notched down to the substrate 30 to form trenches 33 which provide isolation of the adjacent remaining portions of the device layer and their associated conductive tracks 32. A cap wafer 34 is bonded to the device by a bond ring 35 which conforms to the trenches 33 and conductive tracks 32 provided at the upper layer of the device, providing an effective hermetic seal of the operational portion of the device between cap 34 and substrate 30 wafers.

As may be appreciated from FIG. 15, the bond ring material conforms to the irregular surface of the device wafer, having been forced to flow into and fully occupy the trenches by the application of heat and pressure, as described above, to provide, not only a bond between the device and cap wafers, but hermetic sealing of the operational part of the device.

As noted above the bond rings are printed with a width of about 325 μm to 350 μm. However, the width of the bond rings is decreased during the fabrication of the bond rings and during the capping process. This decrease is caused by undercutting during the etching process and by densification caused by expelling at least some of the vehicle liquid from the glass paste material under the effects of the increase in temperature and the decrease in pressure. These decreases in bond width are countered somewhat when the softened glass bond rings are compressed between the cap and device wafers. The bond rings have a height of between about 80 μm and 120 μm before compression and an increase in width of about 1½ times can be expected during compression. The target width of the bond rings is about 325 μm to 350 μm.

It will be noted that, in the accelerometer shown in FIG. 14, the interconnections between the operational part 22 of the accelerometer and the connecting pads 24 are made by conductive tracks 23 which in some cases take circuitous routes to avoid crossing the path of other conductive tracks. This circuitous routing avoids the need to provide a second metallization layer. However, it does require a large overhead in wafer area, which is significantly larger than otherwise would be required. The requirement for the additional area required is further exacerbated by the need to allocate space for the trenches 25 to isolate adjacent conductive runners formed by the silicon layer and the associated metallized tracks, if any.

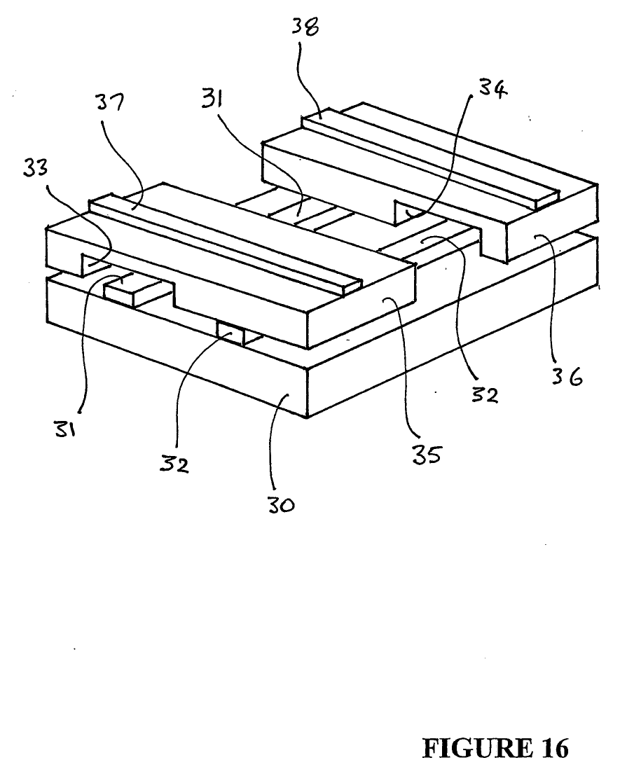

A method of providing double metallization layers allowing the routing of crossed, but electrically isolated, conductive tracks will now be described with reference to the manufacture of an accelerometer and to FIG. 16. It is to be understood that the manufacture of crossed connections using the double metallization layers can be applied to other devices. The reference to the accelerometer is merely for the purposes of this explanation.

During manufacture of an accelerometer, such as the manufacture described above, either before or after the step of etching the cavities 5 in the Pyrex glass substrate 1, as discussed with reference to FIG. 3, a metallization layer, for example a layer of gold on chrome, is sputtered on to the upper face of the substrate. The sputtered layer is then patterned and etched by any suitable method well known in the art of wafer fabrication, to provide a first layer of metallization tracks.

The underside of a semi-conductive silicon wafer, for example wafer 6 as seen in FIGS. 4 and 5, is patterned and wet or dry etched to form one or more cavities. The silicon wafer 6 is then bonded to the substrate 1. The wafer and the substrate are aligned so that the cavities on the underside of the wafer are aligned over the tracks of the first layer of metallization on the upper face of the substrate.

The thickness of the silicon wafer may then be reduced if required, for example by wet chemical etching, lapping, backgrinding, chemical-mechanical polishing, or a combination of these and other techniques, as described above with reference to FIGS. 4 and 5.

A second metallization layer is now deposited onto the topside of the silicon wafer and patterned, for example by a lithography process, to form a second layer of conductive tracks.

The silicon wafer is then patterned, for example by a lithography process as is known, to form the sensor structure of the accelerometer and the electrical runners making connection between the sensor and connection pads to which external connections can be made. The silicon layer can be provided with trenches extending down to the substrate, to isolate the electrical runners.

The silicon runners can be used alone to provide the electrical interconnections or can be augmented by the overlying tracks provided by the second metallization to lower the electrical resistance of the interconnections.

FIG. 16 shows a small fragment of a glass substrate 30 on which a metallization layer has been deposited, for example by sputtering, then patterned and etched by any suitable methods well known in the art of wafer fabrication, to provide a first layer of metallization tracks 31, 32.

A silicon wafer is prepared by etching cavities such as cavities 33, 34 on one face of the wafer. The silicon wafer is bonded to the topside of the substrate with the face having the cavities adjacent the face of the substrate having the metallization tracks.

A second metallization layer is deposited on the outer face of the bonded silicon wafer and then patterned and etched to provide conductive tracks 37, 38.

The silicon layer may then be patterned and etched and other wise treated to form the accelerometer or other device. Trenches may be formed between areas of the silicon wafer to provide electrical isolation.

FIG. 16 shows the silicon wafer divided into two runners 35, 36 separated by a trench. Conductive tracks 37, 38 are formed on respective runners 35, 36, for example to augment the conductivity provided by the runners. The cavities 33, 34 have been provided on the underside of the runners by etching the silicon wafer prior to it being bonded to the glass substrate 30.

As can be seen from FIG. 16, cavity 33 in runner 35 overlies lower metallized track 31 so that there is no electrical connection between the lower track 31 and the runner 35 with its upper track 37. However, because runner 36 is not provided with a cavity overlying lower track 31, the silicon material of the runner 36 provides an intermediate electrical connection between the lower track 31 and the upper track 38.

Similarly, as can also be seen from FIG. 16, cavity 34 in runner 36 overlies lower metallized track 32 so that there is no electrical connection between the lower track 32 and the runner 36 with its upper track 38. However, because runner 35 is not provided with a cavity overlying lower track 32, the silicon material of the runner 35 provides an intermediate electrical connection between the lower track 32 and the upper track 37.

Thus, where a cavity in the underside of the silicon wafer overlies a track of the first metallization layer, a second layer track formed on the topside of the silicon wafer can cross over the underlying first layer track without making electrical interconnection.

In contrast, where no cavity has been formed, the underside of the silicon wafer makes contact with any underlying track of the first metallization layer. In this case, a second layer track formed on the topside of that part of the silicon wafer makes electrical interconnection with the underlying track of the first metallization layer, through the intermediate part of the silicon wafer.

The use of electrically isolated bridges or crossovers of conductive tracks by other conductive tracks or runners allows a more compact layout of interconnections between the sensor, or operational part of the device, and the terminal pads to which external connections will be made. This allows a reduced chip size, which results in a greater device density on the wafer and a lower chip cost.

The foregoing describes the invention including preferred forms thereof. Alterations and modifications as will be obvious to those skilled in the art are intended to be incorporated within the scope hereof as defined in the accompanying claims.

1-59. (canceled)

60. A method of bonding a cap wafer (34) to a device wafer, the device wafer having a substrate (30), a pattern of individual devices fabricated on one face of the substrate, and at least one trench (33) in the one face of the substrate the method including the following steps performed in the order recited:
(a) forming glass bond rings (35) on one face of the cap wafer (12-2), the bond rings being dimensioned and arranged on the cap wafer for respectively surrounding the individual devices on the device wafer when the cap wafer is aligned with the device wafer;
(b) aligning and placing the cap wafer on the device wafer (12-3) with said one face of the cap wafer adjacent the one face of the substrate on which is formed the pattern of individual devices, the two wafers being aligned with the bond rings respectively surrounding the individual devices;
(c) exposing the aligned wafers to a vacuum (12-4), and increasing the temperature (12-6) of the wafers to a predetermined bonding temperature.
(d) applying a biasing force (12-7) to urge the aligned wafers together and to compress the bond rings;
(e) reducing the temperature (12-8) of the wafers to room temperature and removing the force when the temperature of the wafers is less than a first predetermined temperature;
(f) venting the vacuum to atmosphere (12-9) when the temperature of the wafers is less than a second predetermined temperature; and
wherein a full width portion of each trench of a device is crossed by, and substantially occupied by, a portion of the respective bond ring (35).

61. A method of bonding a cap wafer to a device wafer as claimed in claim 60, wherein the bond rings, in conjunction with respective portions of the cap wafer, provide respective hermetic seals around and over the individual devices, after performance of said steps (a) to (f).

62. A method of bonding a cap wafer to a device wafer as claimed in claim 60, wherein step (a) includes the following steps (g) to (n) performed in the order recited:
(g) preparing a glass paste by mixing a glass powder with a vehicle liquid (13-1);
(h) coating the one face of the cap wafer with a layer of the glass paste (13-2);
(i) pre-firing the glass paste at a pre-firing temperature (13-3);
(j) applying a layer of resist over the layer of glass paste (13-4);
(k) soft baking the resist layer (13-5);
(l) photo-lithographically patterning (13-6) and developing (13-7) the applied resist layer;
(m) hard baking the patterned and developed resist layer (13-8); and
(n) etching the pre-fired layer of glass paste (13-9) to form glass bond rings on the one face of the cap wafer, the bond rings being dimensioned and arranged on the cap wafer for respectively surrounding individual devices on the device wafer when the cap wafer is aligned with the device wafer.

63. A method of bonding a cap wafer to a device wafer as claimed in claim 62, wherein the glass paste is prepared in an approximate ratio of 15 gm of glass powder to 2 ml of vehicle liquid.

64. A method of bonding a cap wafer to a device wafer as claimed in claim 62, wherein the glass powder has a nominal particle size of between approximately 15 μm and 40 μm.

65. A method of bonding a cap wafer to a device wafer as claimed in claim 62, wherein the glass powder is a glass frit of approximately 40 μm nominal particle size.

66. A method of bonding a cap wafer to a device wafer as claimed claim 62, wherein the glass powder is a ferro frit of approximately 15 μm nominal particle size.

67. A method of bonding a cap wafer to a device wafer as claimed in claim 62, wherein the pre-firing temperature is between 350° C. and 425° C.

68. A method of bonding a cap wafer to a device wafer as claimed in claim 62, wherein the pre-firing temperature is approximately 400° C.

69. A method of bonding a cap wafer to a device wafer as claimed in claim 62, wherein the resist layer has a thickness of approximately 6 μm.

70. A method of bonding a cap wafer to a device wafer as claimed in claim 62, wherein the soft baking is performed at a temperature of approximately 90° C.

71. A method of bonding a cap wafer to a device wafer as claimed in claim 62, wherein the hard baking is performed at a temperature of approximately 100° C.

72. A method of bonding a cap wafer to a device wafer as claimed in claim 62, wherein the etching of the layer of glass paste uses nitric acid.

73. A method of bonding a cap wafer to a device wafer as claimed in claim 72, wherein the nitric acid has a concentration of approximately 15:1.

74. A method of bonding a cap wafer to a device wafer as claimed claim 62, wherein the Celsius value of the bonding temperature is at least 10% higher than the Celsius value of the pre-firing temperature.

75. A method of bonding a cap wafer to a device wafer as claimed in claim 60, wherein the pressure of the vacuum is approximately 5 mb.

76. A method of bonding a cap wafer to a device wafer as claimed in claim 60, wherein the vacuum is maintained for a predetermined time interval of approximately 2.5 min before the temperature is increased in step (c).

77. A method of bonding a cap wafer to a device as claimed in claim 60, wherein in step (c) the temperature of the wafers is initially increased to approximately 440° C. over a period of about 2 min.

78. A method of bonding a cap wafer to a device wafer as claimed in claim 60, wherein the bonding temperature is approximately 450° C.

79. A method of bonding a cap wafer to a device wafer as claimed in claim 60, wherein said biasing force is increased gradually to a predetermined force.

80. A method of bonding a cap wafer to a device wafer as claimed in claim 79, wherein the predetermined force is between 3000N and 4000N.

81. A method of bonding a cap wafer to a device wafer as claimed in claim 80, wherein the predetermined force is about approximately 3500N.

82. A method of bonding a cap wafer to a device wafer as claimed in claim 79, wherein said biasing force is held at the predetermined force for a predetermined period.

83. A method of bonding a cap wafer to a device wafer as claimed in claim 82, wherein the predetermined period is between 20 min and 40 min.

84. A method of bonding a cap wafer to a device wafer as claimed in claim 83, wherein the predetermined period is approximately 30 min.

85. A method of bonding a cap wafer to a device wafer as claimed in claim 60, wherein said force is initially increased from 0N to approximately 10N and maintained at approximately 10N for about 15 sec.

86. A method of bonding a cap wafer to a device wafer as claimed in claim 85, wherein said force is further increased to approximately 100N and maintained at approximately 100N for about 15 sec.

87. A method of bonding a cap wafer to a device wafer as claimed in claim 86, wherein said force is further increased to approximately 3500N and maintained at approximately 3500N for about 27 min.

88. A method of bonding a cap wafer to a device wafer as claimed in claim 60, wherein said first predetermined temperature is approximately 350° C.

89. A method of bonding a cap wafer to a device wafer as claimed in claim 60, wherein the second predetermined temperature is approximately 250° C.

90. A method of bonding a cap wafer to a device wafer as claimed in claim 60, wherein the cap wafer and the device substrate are each approximately 15.25 cm in diameter.

91. A sealed device, the device being formed on a portion of a device wafer, the device wafer portion having a substrate that includes at least one trench (30), the device being fabricated on one face of the substrate, including the at least one trench, the portion of the device wafer being capped by a portion of a cap wafer (34), the cap wafer portion being bonded to the device wafer portion by a ring bond (35), the ring bond hermetically sealing the device and occupying a portion of the at least one trench.

92. A sealed device as claimed in claim 91, wherein the bond ring is a glass material.

93. A sealed device as claimed in claim 92, wherein the device is an accelerometer.

94. A sealed device as claimed in claim 91, wherein the device is an accelerometer.

95. A sealed device, the device being fabricated from one or more layers formed on one face of a substrate (30) that includes at least one trench, the device having a cap (34) which is bonded to the outermost surface of said layers by a bond ring (21, 35), the bond ring surrounding and hermetically sealing at least an operational portion (22) of the device and occupying a portion of the at least one trench.

96. A sealed device as claimed in claim 95, wherein the bond ring is a glass material.

97. A sealed device as claimed in claim 96, wherein the device is an accelerometer.

98. A sealed device as claimed in claim 95, wherein the device is an accelerometer.

99. A sealed device as claimed in claim 95, wherein the cap is a portion of a silicon wafer.

100. A sealed device as claimed in claim 99, wherein the cap is bonded to the outermost surface of said layers by a thermo-compressive bonding method.

101. A sealed device as claimed in claim 100, wherein the bond ring is a glass material.

102. A sealed device as claimed in claim 101, wherein the device is an accelerometer.

103. A sealed device as claimed in claim 99, wherein the device is an accelerometer.

104. A sealed device as claimed in claim 99, wherein the bond ring is a glass material.

105. A sealed device as claimed in claim 99, wherein the device is an accelerometer.

106. A sealed device as claimed in claim 95, wherein the cap is bonded to the outermost surface of said layers by a thermo-compressive bonding method.

107. A sealed device as claimed in claim 106, wherein the device is an accelerometer.

108. A sealed device as claimed in claim 106, wherein the bond ring is a glass material.

109. A sealed device as claimed in claim 108, wherein the device is an accelerometer.

110. A sealed device as claimed in claim 110, wherein the device is an accelerometer.

111. A sealed device as claimed in any one of claims 92-110 wherein the cap is bonded to the outermost surface of said layers by the method as claimed in any one of claims 60-90.

112. A method of fabricating an accelerometer including the steps of:
etching at least one cavity (5) into the top side of a substrate (1) of insulating material, bonding a top layer (6) of material onto the top side of the substrate,
depositing metallization (7) onto the layer of material, and
etching the top layer of material to form a sensor structure suspended over each cavity.

113. A method of fabricating an accelerometer as claimed in claim 112 further including the step of masking the substrate before each etching step.

114. A method fabricating an accelerometer as claimed in claim 113, further including the step of patterning the mask (4).

115. A method of fabricating an accelerometer as claimed in claim 114, further including the step of performing an etch back after each etching step to remove unwanted masking layer.

116. A method of fabricating an accelerometer as claimed in claim 114, further including the step of patterning the masking layer to a pattern of beams before etching the top layer of material to form the sensor structure.

117. A method of fabricating an accelerometer as claimed in claim 116, further including the step of performing an etch back after each etching step to remove unwanted masking layer.

118. A method of fabricating an accelerometer as claimed in claim 113, further including the step of patterning the masking layer to a pattern of beams before etching the top layer of material to form the sensor structure.

119. A method of fabricating an accelerometer as claimed in claim 118, further including the step of performing an etch back after each etching step to remove unwanted masking layer.

120. A method of fabricating an accelerometer as claimed in claim 113, further including the step of performing an etch back after each etching step to remove unwanted masking layer.

121. A sealed device as claimed in any one of claims 91-111, wherein the device is an accelerometer fabricated by the method of any one of claims 112-114, 116, 118 and 120.

122. A method of manufacturing an accelerometer including the steps of:
fabricating said accelerometer by the method as claimed in any one of claims 112-114, 116, 118 and 120; and
encapsulating the said fabricated accelerometer by the method as claimed in any one of claims 60-90.

123. An accelerometer including:
a bottom substrate layer (1) of insulating material,
a top layer (6) bonded to the bottom layer,
at least one cavity (5) in the bottom substrate layer formed before the top layer is bonded to the bottom layer,
a capacitive sensor structure formed in the top layer and suspended over the cavity, and
at least one point (10) suitable for electrical connection in contact with each part of the capacitive sensor structure formed before the capacitive sensor structure is formed.

124. An accelerometer as claimed in claim 123, wherein the top layer is formed of a silicon material.

125. A sealed device as claimed in any one of claims 99-111, wherein the device is an accelerometer as claimed in any one of claims 123-124.

126. A method of manufacturing a wafer fabricated device including the steps of:
(o) depositing a first metallization onto one side of a substrate of insulating material (30),
(p) selectively etching the deposited first metallization to provide a pattern including at least one conductive track (31, 32),
(q) selectively etching at least one cavity (33, 34) in a first face of a semi-conducting wafer (35, 36),
(r) bonding the etched first face of the wafer to the one side of the substrate, so that the at least one cavity overlies the at least one conductive track,
(s) selectively etching the wafer to electrically isolate conductive runners on the wafer (35, 36).

127. A method manufacturing a wafer fabricated device as claimed in claim 126 further including the steps of depositing a second metallization onto a second face of the bonded wafer, and selectively etching the second metallization to provide a pattern including at least one conductive path (37, 38), between the steps of bonding the wafer and the substrate and selectively etching the wafer.

128. A method of manufacturing a wafer fabricated device as claimed in claim 127, wherein the substrate is glass.

129. A method of manufacturing a wafer fabricated device as claimed in claim 126, wherein the wafer is a silicon wafer.

130. A method of manufacturing an accelerometer including the steps of:
manufacturing a device wafer by the method as claimed in any one of claims 126-129;
fabricating said accelerometer by the method as claimed in any one of claims 112-114, 116, 118 and 120; and
encapsulating the said fabricated accelerometer by the method as claimed in any one of claims 60-90.
